(19) United States
(12) Patent Application Publication
(10) Pub. No.: US 2026/0262391 A1
(43) Pub. Date: Sep. 3, 2026

(54) DISPLAY PANEL, ELECTRONIC DEVICE INCLUDING THE DISPLAY PANEL AND MANUFACTURING METHOD FOR THE DISPLAY PANEL

(71) Applicant: Samsung Display Co., Ltd., Yongin-si (KR)

(72) Inventors: Jungsu LEE, Yongin-si (KR); Dong-Yoon SO, Yongin-si (KR); Junghyun LEE, Yongin-si (KR)

(73) Assignee: Samsung Display Co., Ltd., Yongin-si (KR)

(21) Appl. No.: 19/427,378

(22) Filed: Dec. 19, 2025

(30) Foreign Application Priority Data
Feb. 28, 2025 (KR) 10-2025-0026987

(51) Int. Cl. H10K 59/122; H10K 59/12; H10K 59/80; H10K 102/00

(52) U.S. Cl. CPC H10K 59/122; H10K 59/1201; H10K 59/8731; H10K 2102/351

(57) ABSTRACT

Provided is a display panel including a base layer including a display region and a non-display region adjacent to the display region, a pixel definition layer on the base layer and having pixel openings defined therein, and a display element layer including light-emitting elements in the pixel openings and first spacers on the pixel definition layer. The first spacers overlap the display region, the first spacers do not overlap the pixel openings, and the first spacers have a first thickness. The display panel also includes a dam portion in the non-display region, and second spacers between the dam portion and the first spacers. Each second spacer has a second thickness smaller than the first thickness.

### CROSS-REFERENCE TO RELATED APPLICATIONS

This U.S. non-provisional patent application claims priority under 35 U.S.C. § 119 to Korean Patent Application No. 10-2025-0026987, filed on Feb. 28, 2025, the entire contents of which are hereby incorporated by reference.

### BACKGROUND

Some example embodiments relate to a display panel with improved reliability and a manufacturing method for the display panel.

Multimedia devices such as a television, a mobile phone, a tablet PC, a navigation unit, and a game console include a display panel which displays an image to a user through a display screen. A deposition process may be performed in a process of manufacturing a display panel. A deposition mask may be used to perform the deposition process. However, when a deposition mask is in relatively close contact with a target substrate, the target substrate may be dented or damaged.

### SUMMARY

Some example embodiments provide a display panel with improved reliability in a deposition process and a manufacturing method for the same.

According to some example embodiments of the inventive concepts, a display panel includes a base layer including a display region and a non-display region adjacent to the display region, a pixel definition layer on the base layer and having pixel openings defined therein, and a display element layer including light-emitting elements in the pixel openings and first spacers on the pixel definition layer. The first spacers overlap the display region, the first spacers do not overlap the pixel openings, and each first spacer has a first thickness. The display panel also include a dam portion in the non-display region and second spacers between the dam portion and the first spacers. Each second spacer has a second thickness smaller than the first thickness.

In some example embodiments, the second spacers may overlap the display region, and in a cross-sectional view, a width of a bottom surface of each of the second spacers may be smaller than a width of a bottom surface of each of the first spacers.

In some example embodiments, the second thickness of each second spacer is 50% to 80% of the first thickness of each first spacer.

In some example embodiments, a number of the second spacers per unit area may be more than a number of the first spacers per unit area.

In some example embodiments, an upper surface of the first spacers may be flat, and an upper surface of the second spacers may be flat.

In some example embodiments, the display panel further includes an encapsulation layer on the pixel definition layer. The encapsulation layer may include a first inorganic encapsulation film, an organic encapsulation film, and a second inorganic encapsulation film which are arranged in series on the pixel definition layer, and wherein a maximum thickness of the organic encapsulation film at a portion overlapping the first spacers may be greater than a maximum thickness of the organic encapsulation film at a portion overlapping the second spacers.

In some example embodiments, the organic encapsulation film may cover the second spacers, and a maximum thickness of the organic encapsulation film at a portion overlapping the second spacers may be smaller than a thickness of the second spacers.

In some example embodiments, the first spacers and the second spacers may be formed through a same process and may include a same material.

In some example embodiments, each of the first thickness of the first spacers and the second thickness of the second spacers may be smaller than a thickness of the dam portion.

In some example embodiments, in a cross-sectional view, the first spacers and the second spacers may have a width decreasing in a direction away from the base layer.

In some example embodiments, the first spacers and the second spacers may each include a single layer.

In some example embodiments of the inventive concepts, a manufacturing method for a display panel includes providing a preliminary-display panel including a base layer and a pixel definition layer disposed on the base layer and having pixel openings defined therein, forming a photoresist layer on the pixel definition layer, arranging, on the preliminary-display panel, a spacer mask having first mask openings and second mask openings defined therein, exposing the photoresist layer, and forming first spacers and second spacers by etching the photoresist layer.

In some example embodiments, an area of the first mask openings may be smaller than an area of the second mask openings.

In some example embodiments, the manufacturing method may further include arranging, on the preliminary-display panel, a deposition mask having deposition openings defined therein, and depositing a light-emitting element on the preliminary-display panel through the deposition mask.

In some example embodiments, in the arranging of the deposition mask, the deposition mask may be arranged on the first spacers.

In some example embodiments, the deposition mask may be a fine metal mask (FMM).

In some example embodiments, the deposition mask may be an open mask, and at least one second spacer is disposed in the non-display region.

In some example embodiments, the manufacturing method may further include forming a first inorganic encapsulation film on the pixel definition layer, forming an organic encapsulation film on the first inorganic encapsulation film, and forming a second inorganic encapsulation film on the organic encapsulation film.

In some example embodiments, the forming of the organic encapsulation film may be performed by one of a spin coating process, a slit coating process, and an inkjet process, and a maximum thickness of the organic encapsulation film at a portion overlapping the first spacers may be greater than a maximum thickness of the organic encapsulation film at a portion overlapping the second spacers.

In some example embodiments, the organic encapsulation film may cover the second spacers, and a thickness of the organic encapsulation film at a portion overlapping the second spacers may be smaller than a thickness of the second spacers.

In some example embodiments, the first spacers and the second spacers may overlap the display region, and the second spacers may be disposed closer to an outer side of the preliminary-display panel than the first spacers.

In some example embodiments, the spacer mask may be a half-tone mask.

In some example embodiments of the inventive concepts, an electronic device includes a display panel including a base layer including a display region and a non-display region adjacent to the display region, a pixel definition layer on the base layer and having pixel openings defined therein, and a display element layer including light-emitting elements in the pixel openings and first spacers on the pixel definition layer. The first spacers overlap the display region, the first spacers do not overlap the pixel openings, and each first spacers has a first thickness. The display panel also includes a dam portion in the non-display region, and second spacers between the dam portion and the first spacers. Each second thickness is smaller than the first thickness. The electronic device also includes a processor connected to the display panel, and a window on the display panel.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a block diagram of an electronic device according to some example embodiments of the inventive concepts.

FIG. 2 is a schematic view of different electronic devices.

FIG. 3 is a perspective view of an electronic device according to some example embodiments of the inventive concepts.

FIG. 4 is an exploded perspective view of an electronic device according to some example embodiments of the inventive concepts.

FIG. 5A is a cross-sectional view of a display module according to some example embodiments of the inventive concepts.

FIG. 5B is a cross-sectional view of a display panel according to some example embodiments of the inventive concepts.

FIG. 6 is a plan view of a display panel according to some example embodiments of the inventive concepts.

FIG. 7 is an enlarged plan view of region AA′ of FIG. 6.

FIG. 8 is a cross-sectional view taken along line I-I′ of FIG. 7.

FIG. 9 is a flow chart of a manufacturing method for a display panel according to some example embodiments of the inventive concepts.

FIGS. 10A, 10B, 10C, 10D, and 10E are diagrams illustrating operations of a manufacturing method for a display panel according to some example embodiments of the inventive concepts.

FIG. 11 is an enlarged plan view of a region of a display panel according to some example embodiments of the inventive concepts.

FIG. 12 is a diagram illustrating one step of a manufacturing process of a display panel according to some example embodiments of the inventive concepts.

### DETAILED DESCRIPTION

Embodiments of the inventive concepts may be variously modified and have various forms, but specific embodiments will be illustrated in the drawings and described in detail in the description. However, this is not intended to limit the inventive concepts to a specific disclosed form, and it should be understood that all changes, equivalents, and alternatives included in the spirit and scope of the inventive concepts are included.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concepts. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the inventive concepts are described with reference to the drawings.

In the above, description has been made with reference to example embodiments of the inventive concepts, but those skilled or of ordinary skill in the art may understand that various modifications and changes may be made to the inventive concepts insofar as such modifications and changes do not depart from the spirit and technical scope of the inventive concepts set forth in the claims to be described later. Therefore, the technical scope of the inventive concepts is not to be limited to the contents stated in the detailed description of the specification, but should be determined by the claims.

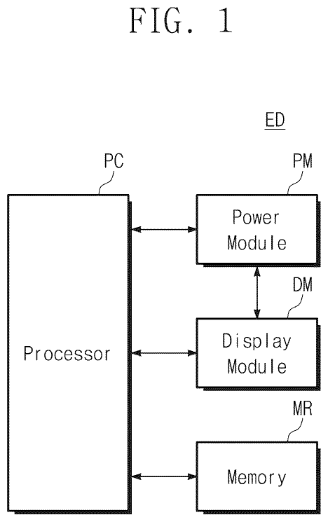

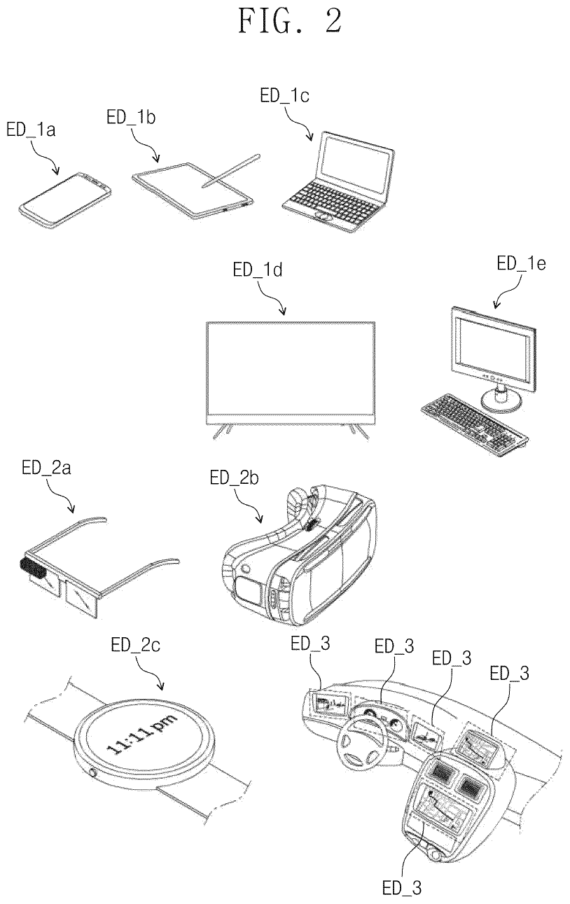

FIG. 1 is a block diagram of an electronic device according to some example embodiments of the inventive concepts. FIG. 2 is a schematic view of different electronic devices according to some example embodiments.

An electronic device may be provided in various forms. The electronic device may further include a module or a device having another additional function.

Referring to FIG. 1, an electronic device ED according to some example embodiments may include a display module DM, a processor PC, a memory MR, and/or a power module PM.

The processor PC may include at least one among a central processing unit (CPU), an application processor (AP), a graphic processing unit (GPU), a communication processor (CP), an image signal processor (ISP), and a controller.

Data information required for an operation of the processor PC or the display module DM may be stored in the memory MR. When the processor PC executes an application stored in the memory MR, an image data signal and/or an input control signal may be transferred to the display module DM, and the display module DM may process the provided signal and output image information through a display screen.

The power module PM may include a power supply module such as a power adapter or a battery device, and a power conversion module which converts power supplied by the power supply module and generates power required for an operation of the electronic device ED.

Some individual modules included in functionally one module may be included in the display module DM, and the other thereof may be provided in the electronic device ED separately from the display module DM.

Referring to FIG. 2, the electronic devices may be wearable electronic devices including a display module, such as smart glasses ED-2a, a head-mounted display ED-2b and a smart watch ED-2c, automotive electronic devices ED-3 including a display module, such as a center information display (CID) disposed on an instrument panel, a center fascia, and a dashboard of an automobile and a room mirror display, and the like as well as electronic devices for displaying images, such as a smartphone ED-1a, a tablet PC ED-1b, a laptop ED-1c, a television ED-1d, and a desk monitor ED-1e.

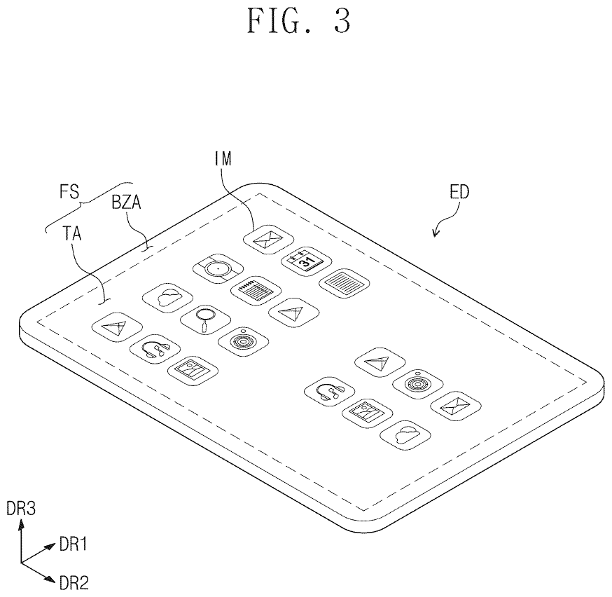

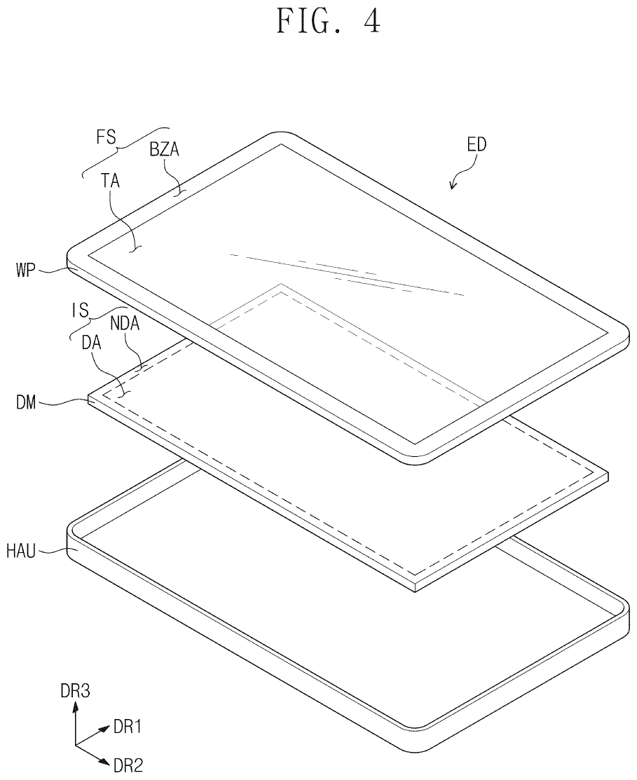

FIG. 3 is a perspective view of an electronic device according to some example embodiments of the inventive concepts. FIG. 4 is an exploded perspective view of an electronic device according to some example embodiments of the inventive concepts.

For the purposes of discussion herein, an electronic device ED may be consider having a rectangular shape having shorter sides extending in a first direction DR1 and longer sides extending in a second direction DR2 in a plan view (or top view). However, example embodiments of the inventive concepts are not limited thereto, and the electronic device ED may have various other shapes such as a circular shape and a polygonal shape.

The electronic device ED may display an image IM in a third direction DR3 through a display surface FS that is parallel to (or lies in) a plane defined by the first direction DR1 and the second direction DR2. The third direction DR3 may be substantially parallel to a normal direction of the display surface FS. The display surface FS on which the image IM is displayed may correspond to a front surface of the electronic device ED. The image IM may include a static image as well as a dynamic image. FIG. 3 illustrates icon images as an example of the image IM.

In some example embodiments, a front surface (or an upper surface) and a rear surface (or a lower surface) of each of members or units may be defined with respect to a direction in which the image IM is displayed. The front surface and the rear surface may be opposite to each other in the third direction DR3, and a normal direction of each of the front surface and the rear surface may be parallel to the third direction DR3. A separation distance between the front surface and the rear surface defined along the third direction DR3 may correspond to a thickness of a member (or a unit).

As used herein, “in a plan view” may be defined as a state of being viewed in the third direction DR3. As used herein, “in a cross-sectional view” may be defined as a state of being viewed in the first direction DR1 or the second direction DR2. Meanwhile, directions indicated by the first to third directions DR1, DR2, and DR3 may have relative concepts and may be changed into other directions.

In the electronic device ED, the display surface FS on which the image IM is displayed may correspond to the front surface of the electronic device ED and may correspond to a front surface FS of a window WP (see FIG. 4). Hereinafter, the display surface and the front surface of the electronic device ED and the front surface of the window WP will be denoted as the same reference numerals or symbols. Meanwhile, the electronic device ED may include a foldable display device including a folding region and a non-folding region, a bending display device including at least one bending portion, or the like.

Referring to FIG. 4, an electronic device ED according to some example embodiments may include a window WP, a display module DM, and a housing HAU.

The window WP may include an optically transparent insulating material. The window WP may include a transmission region TA and a bezel region BZA. A user may view an image provided through the transmission region TA corresponding to a front surface FS of the window WP.

The transmission region TA may be an optically transparent region. The bezel region BZA may be a region that has a relatively low light transmittance compared to the transmission region TA. The bezel region BZA may have a predetermined (or desired or given) color. The bezel region BZA may be adjacent to the transmission region TA and surround the transmission region TA. The bezel region BZA may define a shape of the transmission region TA. However, example embodiments are not limited to the illustration, and the bezel region BZA may be disposed adjacent to only one side of the transmission region TA or may be partially omitted.

FIGS. 3 and 4 each illustrate the transmission region TA having a quadrangular shape. However, this is illustrated as an example, and example embodiments are not limited thereto, and the transmission region TA may have various other shapes depending on application and/or design and the shape of the transmission region TA is not limited to any particular shape.

The display module DM may be disposed under or below the window WP. The display module DM may be a component which generates the image IM. The image IM generated in the display module DM is displayed on a display surface IS and viewed by a user from the outside through the transmission region TA.

The display module DM includes a display region DA and a non-display region NDA. The display region DA may be a region activated in response to an electrical signal. The non-display region NDA may be a region covered with the bezel region BZA. The non-display region NDA is adjacent to the display region DA. The non-display region NDA may surround the display region DA.

The housing HAU may accommodate the display module DM. The housing HAU may provide a base space in which the display module DM is disposed. The housing HAU may be disposed covering the display module DM so that an upper surface which is the display surface IS of the electronic device ED is exposed. The housing HAU may cover a side surface and a bottom surface of the display module DM and expose an entire upper surface of the display module DM. However, example embodiments are not limited thereto, and the housing HAU may cover not only the side surface and the bottom surface of the display module DM but also a portion of the upper surface of the display module DM.

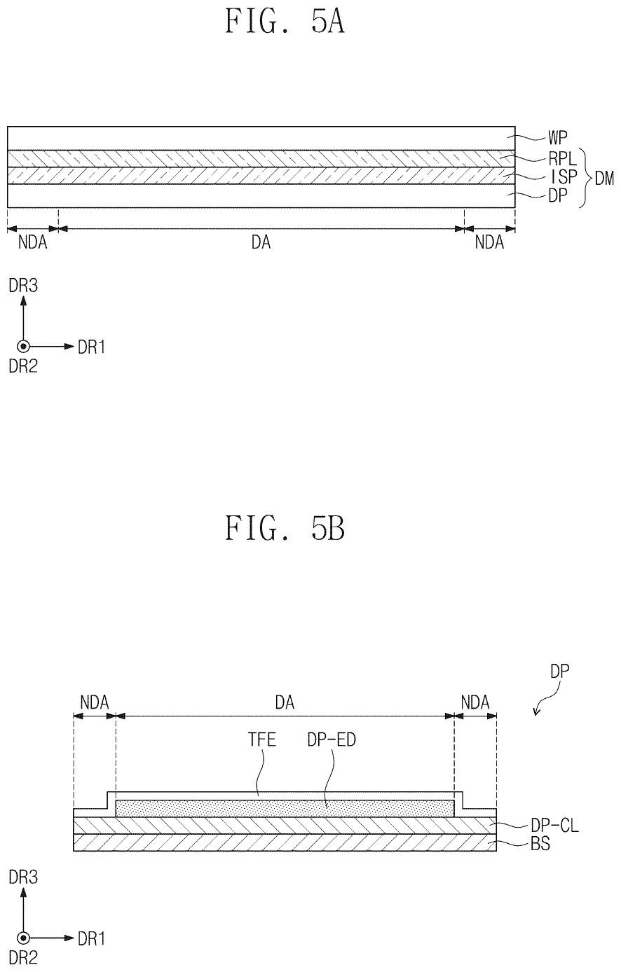

FIG. 5A is a cross-sectional view of a display module according to some example embodiments of the inventive concepts. FIG. 5B is a cross-sectional view of a display panel according to some example embodiments of the inventive concepts.

Referring to FIG. 5A, the display module DM may include a display panel DP, an input sensing part ISP, an anti-reflection layer RPL, and a window WP. However, example embodiments of the inventive concepts are not limited thereto. For example, the input sensing part ISP or the anti-reflection layer RPL may be omitted.

The display panel DP of FIG. 5A may be an emissive display panel and is not particularly limited. For example, the display panel DP may be an organic light-emitting display panel or an inorganic light-emitting display panel. An emission layer of the organic light-emitting display panel may include an organic light-emitting material. An emission layer of the inorganic light-emitting display panel may include quantum dots, quantum rods, and the like. Hereinafter, the display panel DP is described as an organic light-emitting display panel.

The input sensing part ISP may be disposed on the display panel DP. The input sensing part ISP may include a plurality of sensor portions for sensing an external input in a capacitive manner. When the display module DM is manufactured, the input sensing part ISP may be directly manufactured on the display panel DP. However, example embodiments of the inventive concepts are not limited thereto, and the input sensing part ISP may be manufactured as a panel separate from the display panel DP, and may be attached to the display panel DP via an adhesive layer.

The anti-reflection layer RPL may be disposed on the input sensing part ISP. The anti-reflection layer RPL may be directly formed on the input sensing part ISP or coupled to the input sensing part ISP via an adhesive layer. The anti-reflection layer RPL may be defined as an external light anti-reflection film. The anti-reflection layer RPL may reduce reflectance for external light incident to the display panel DP from above the electronic device ED.

The window WP may be disposed on the anti-reflection layer RPL. The window WP may be directly formed on the anti-reflection layer RPL or coupled to the anti-reflection layer RPL via an adhesive layer. The window WP may protect the display panel DP, the input sensing part ISP, and the anti-reflection layer RPL from external scratches and impacts.

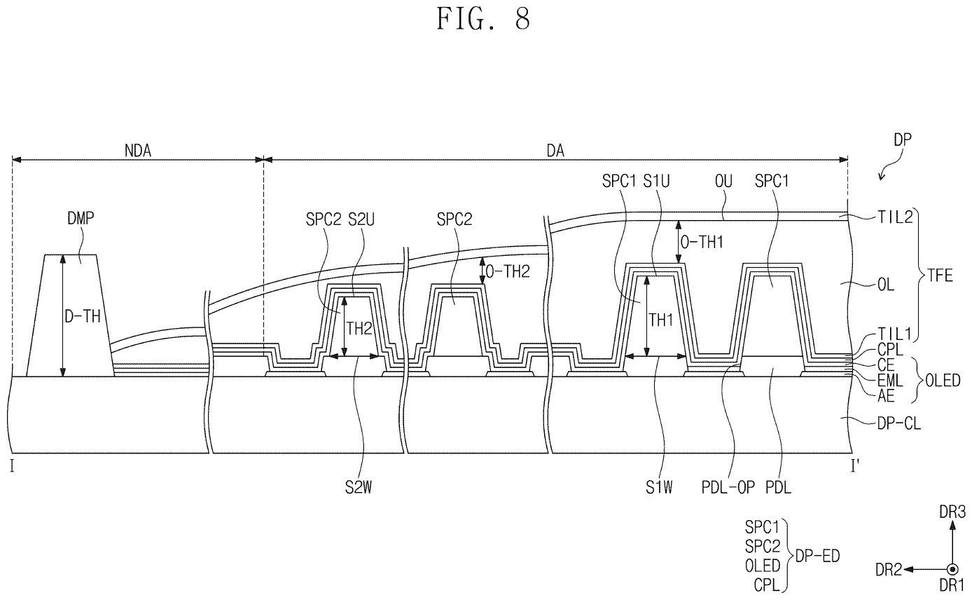

Referring to FIG. 5B, a display panel DP may include a base layer BS, a circuit element layer DP-CL disposed on the base layer BS, a display element layer DP-ED disposed on the circuit element layer DP-CL, and an encapsulation layer TFE disposed on the display element layer DP-ED, or alternatively on the pixel definition layer PDL (FIG. 8).

The base layer BS may include a display region DA and a non-display region NDA around the display region DA. The base layer BS may include glass or a flexible plastic material such as polyimide (PI). The display element layer DP-ED may be disposed on the display region DA.

Pixels may be disposed in the circuit element layer DP-CL and the display element layer DP-ED. The pixels may each include a driving circuit including a transistor disposed in the circuit element layer DP-CL and a light-emitting element disposed in the display element layer DP-ED and connected to the transistor.

The encapsulation layer TFE may cover the display element layer DP-ED. The encapsulation layer TFE may protect the pixels from moisture, oxygen, and external foreign substances.

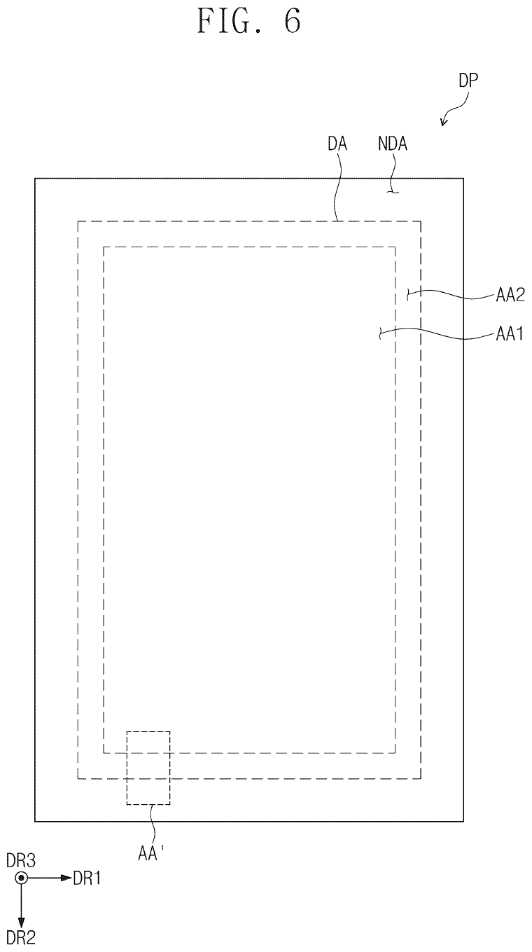

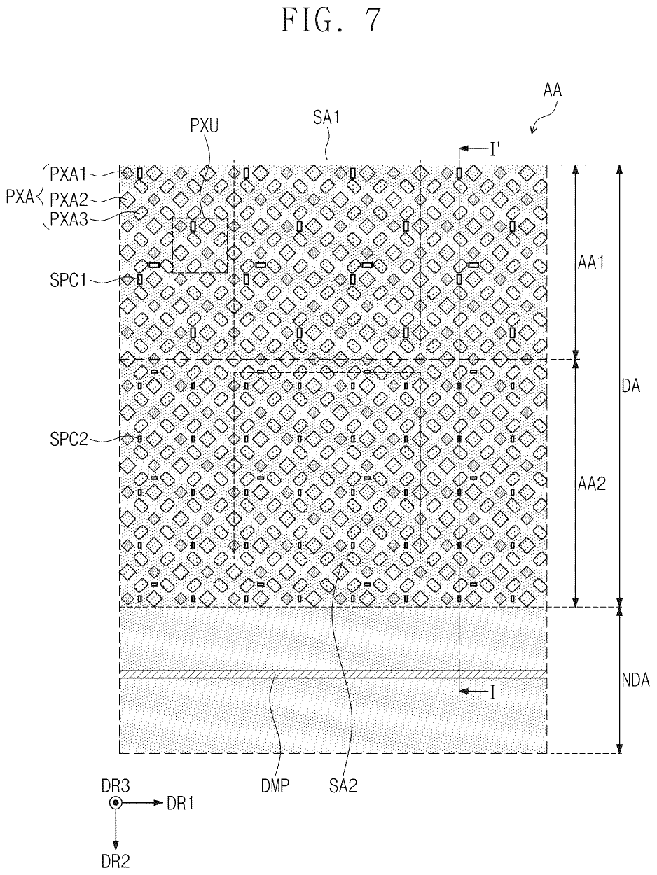

FIG. 6 is a plan view of a display panel according to some example embodiments of the inventive concepts. FIG. 7 is an enlarged plan view of region AA′ of FIG. 6.

Referring to FIGS. 6 and 7 together, a display panel DP may include a display region DA and a non-display region NDA adjacent to the display region DA.

First to third pixels PXA1, PXA2 and PXA3 (collectively, pixels PXA), first spacers SPC1 and second spacers SPC2 may be disposed in the display region DA.

In some example embodiments, two first pixels PXA1, two second pixels PXA2, and four third pixels PXA3 may constitute one pixel unit PXU. Pixel units PXU may be arranged in the first direction DR1 and the second direction DR2. However, a configuration or arrangement of the pixels PXA1, PXA2 and PXA3 is illustrated as an example and is not limited to the illustration of FIG. 7. For example, the pixels PXA1, PXA2 and PXA3 may be arranged in a Diamond™ shape or a Pentile™ shape. In some example embodiments, the pixels PXA1, PXA2 and PXA3 may each include a light-emitting element and a driving circuit. In some example embodiments, the light-emitting element may be or include a light-emitting diode (LED).

The display region DA may include a first region AA1 and a second region AA2 adjacent to the first region AA1. For the purposes of discussion herein, the first region AA1 may be defined as a region in which the first spacers SPC1 are disposed. The second region AA2 may be defined as a region in which the second spacers SPC2 are disposed.

The first spacers SPC1 and the second spacers SPC2 may be disposed between the pixels PXA.

The second spacers SPC2 may be disposed between a dam portion DMP and the first spacers SPC1.

The second spacers SPC2 may have a smaller size than the first spacers SPC1. This will be described later with reference to FIG. 8.

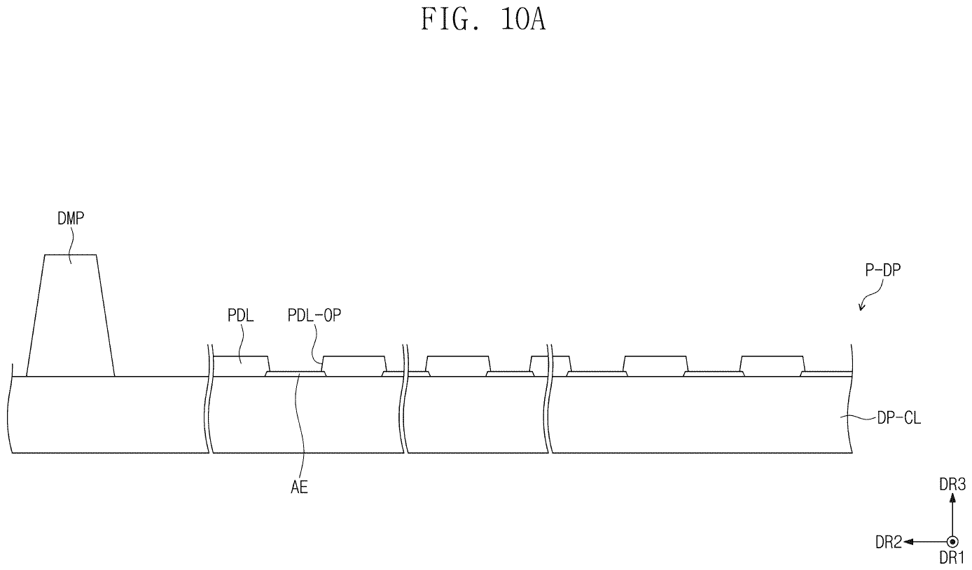

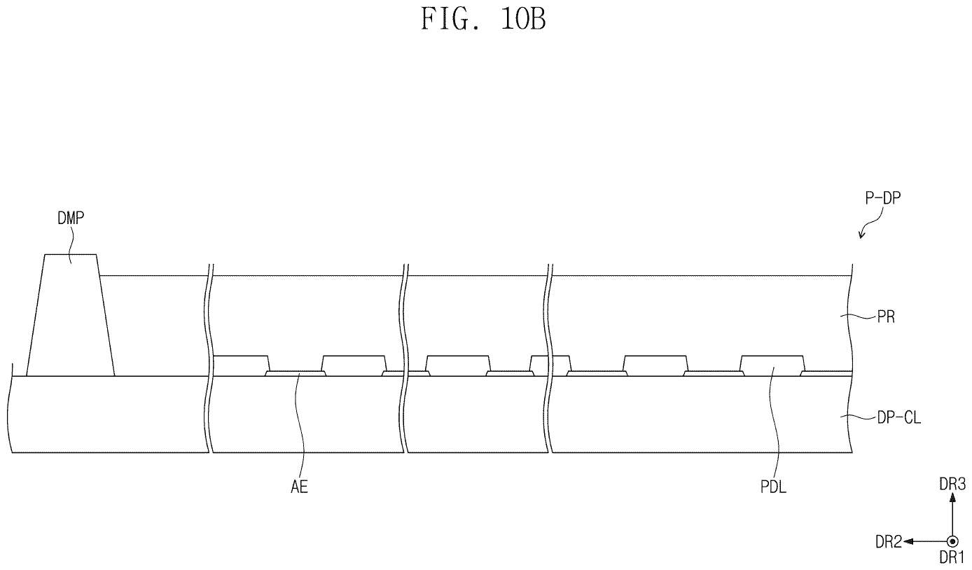

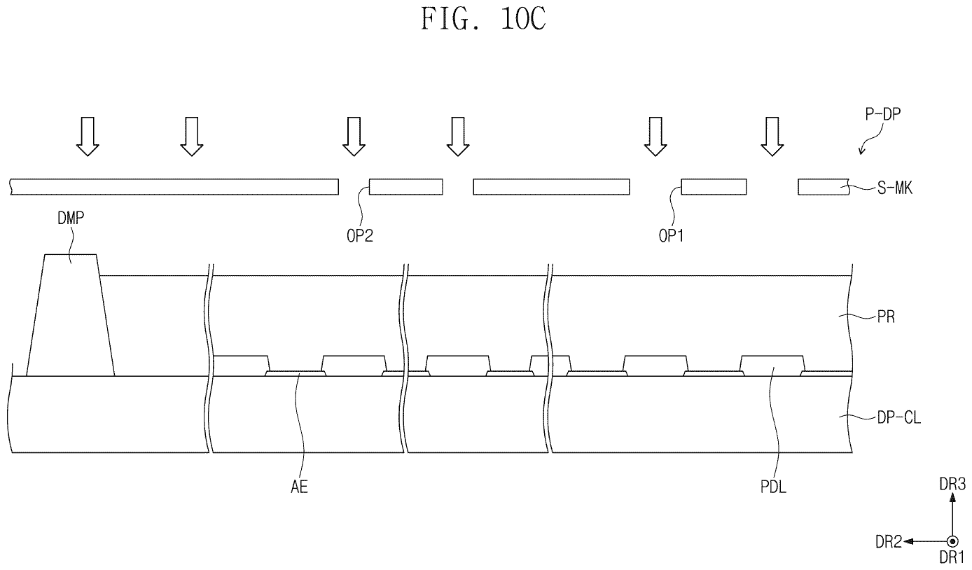

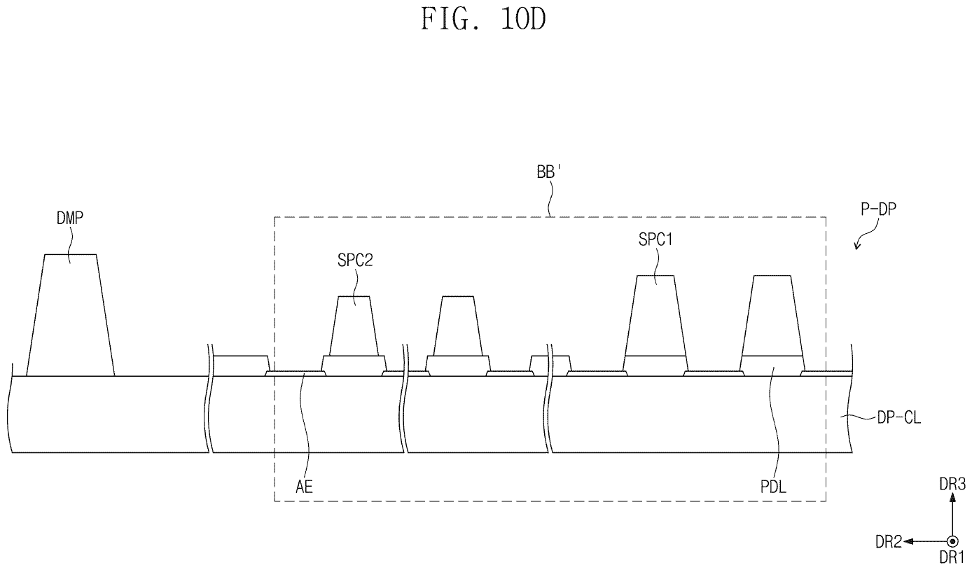

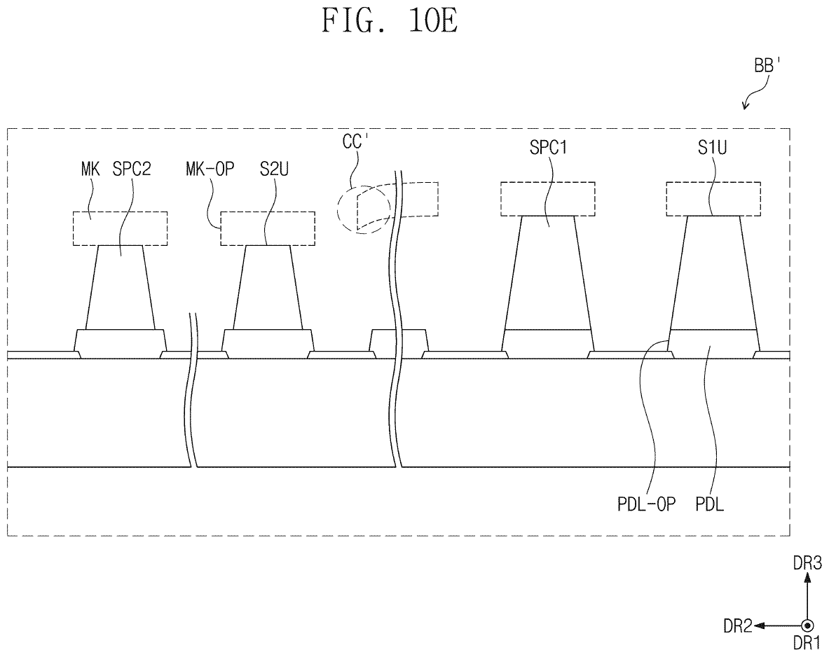

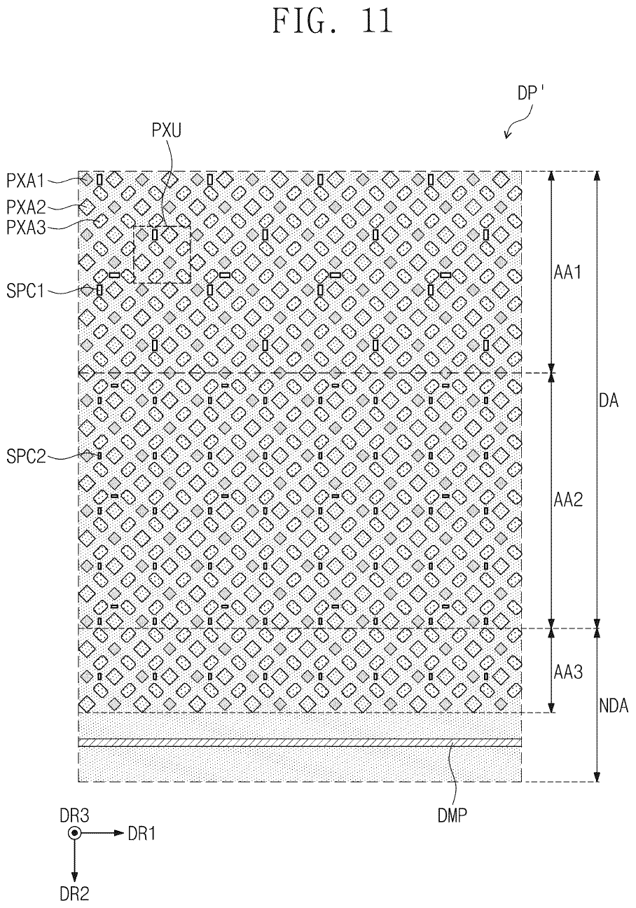

The first and second spacers SPC1 and SPC2 may serve (or function or operate) as a support on which a deposition mask MK (see FIG. 10E) is disposed in a manufacturing process of the display panel DP. The first and second spacers SPC1 and SPC2 may function (or operate) to prevent or avoid or limit the deposition mask MK from contacting with a component except the first and second spacers SPC1 and SPC2 among components included in the display panel DP.

FIG. 7 illustrates a first unit region SA1 in which the first spacers SPC1 are disposed and a second unit region SA2 in which the second spacers SPC2 are disposed as an example. The first unit region SA1 and the second unit region SA2 may have the same area. The number of the second spacers SPC2 disposed in the second unit region SA2 may be equal to or more than the number of the first spacers SPC1 disposed in the first unit region SA1. The number of the second spacers SPC2 per unit area may be more than or equal to the number of the first spacers SPC1 per unit area. Accordingly, even if the second spacers SPC2 have a smaller size than the first spacers SPC1, the second spacers SPC2 may sufficiently support the mask MK, as disclosed below.

Referring to FIG. 7, the dam portion DMP may be disposed in the non-display region NDA. The dam portion DMP may serve or operate or function to block an organic material from overflowing to an outer periphery of the display panel DP in a process of depositing an organic encapsulation film OL (see FIG. 8) to be described later.

FIG. 8 is a cross-sectional view taken along line I-I′ of FIG. 7.

For convenience of description, in the illustration, components, among components included in the display panel DP, disposed below a circuit element layer DP-CL are omitted, two first spacers SPC1 and two second spacers SPC2 are illustrated, and the remaining first and second spacers SPC1 and SPC2 are omitted. Also, the pixels PXA1, PXA2 and PXA3 are omitted in FIG. 7, for the clarity of illustration.

A display element layer DP-ED may include light-emitting elements OLED, the first spacers SPC1, the second spacers SPC2, and a capping layer CPL.

The light-emitting elements OLED may each include a first electrode AE, an emission layer EML, and a second electrode CE. In some example embodiments, the light-emitting elements OLED may each further include an electron control layer disposed between the first electrode AE and the emission layer EML and a hole control layer disposed between the emission layer EML and the second electrode CE.

The capping layer CPL may cover the second electrode CE. The capping layer CPL may function or may be configured to protect the second electrode CE.

The first and second spacers SPC1 and SPC2 may be disposed on a pixel definition layer PDL. The first and second spacers SPC1 and SPC2 may not overlap pixel openings PDL-OP at least partially defined by the pixel definition layer PDL. In other words, the first and second spacers SPC1 and SPC2 may be offset from the pixel openings PDL-OP.

An upper surface S1U of the first spacers SPC1 and an upper surface S2U of the second spacers SPC2 may be flat or planar. Thus, the deposition mask MK (see FIG. 10E) may be stably supported in a deposition process to be described later.

The first spacers SPC1 and the second spacers SPC2 may be formed through the same process and may include the same material. For example, the first spacers SPC1 and the second spacers SPC2 may include a photoresist material which is cured by light. The first spacers SPC1 and the second spacers SPC2 may each include a single layer.

In a cross-sectional view, the first spacers SPC1 and the second spacers SPC2 may each have a width decreasing in the third direction. The first spacers SPC1 and the second spacers SPC2 may each have a width decreasing in a direction away from the base layer BS.

The first spacers SPC1 may have a first thickness TH1. The first thickness TH1 of the first spacers SPC1 may be smaller than a thickness D-TH of the dam portion DMP.

The second spacers SPC2 may be disposed on an outer side or periphery of the display panel DP with respect to the first spacers SPC1 and may prevent or avoid or limit a “dent defect”, which may occur at an outer peripheral portion of the display region DA, caused by the deposition mask MK. In this specification, the term “dent defect” phenomenon caused by the deposition mask MK may be used to refer to an issue in which the first spacers SPC1, the second spacers SPC2, and/or the light-emitting elements OLED are damaged by being in contact with the deposition mask MK. When dent defect occurs at the display panel DP, a grey dark spot (GDS) may occur, or functionality of the light-emitting elements OLED may be deteriorated.

The second spacers SPC2 may have a smaller size than the first spacers SPC1. In some example embodiments, a second thickness TH2 of the second spacers SPC2 may be equal to or smaller than the first thickness TH1 of the first spacers SPC1.

The second thickness TH2 may be 50% (or about 50%) to 80% (or about 80%) of the first thickness TH1. When the second thickness TH2 is greater than 80% (or about 80%) of the first thickness TH1, a moisture permeation path of moisture/oxygen may be formed passing through an organic encapsulation film OL or a second inorganic encapsulation film TIL2. When the second thickness TH2 is smaller than 50% (or about 50%) of the first thickness TH1, the deposition mask MK may not be stably supported.

The second thickness TH2 of the second spacers SPC2 may be smaller than the thickness D-TH of the dam portion DMP.

In a cross-sectional view, a width S2W of a bottom surface of the second spacers SPC2 may be smaller than a width S1W of a bottom surface of the first spacers SPC1. In some example embodiments, the bottom surface of the first spacers SPC1 and the second spacers SPC2 may be coplanar with the top or upper surface of the pixel definition layer PDL.

An encapsulation layer TFE may include a first inorganic encapsulation film TIL1, the organic encapsulation film OL and the second inorganic encapsulation film TIL2 which are arranged in series or sequentially disposed or formed on the pixel definition layer PDL. In some example embodiments, the organic encapsulation film OL may be formed using an inkjet method or a spin coating method.

Thus, an upper surface OU of the organic encapsulation film OL may be formed getting closer to the circuit element layer DP-CL in a direction toward an outer periphery of the display panel DP. Stated otherwise, at least portions of the upper surface OU of the organic encapsulation film OL may bend or slope towards the circuit element layer DP-CL in the direction of the outer periphery of the display panel DP, for example, in the direction from right to left in FIG. 8.

Since the second spacers SPC2 have a relatively smaller size (e.g., cross-sectional area) than the first spacers SPC1 and are disposed closer to an outer periphery of the display panel DP with respect to the first spacers SPC1, even if the upper surface S2U of the second spacer SPC2 is dented by the mask MK, a foreign substance or debris generated due to denting may be captured or contained in the organic encapsulation film OL and damage to the second inorganic encapsulation film TIL2 due to the foreign substance or debris may be limited or reduced. Accordingly, reliability of the display panel DP may be maintained or improved. Since the second spacer SPC2 has a small size, a moisture permeation path of moisture/oxygen may be prevented or limited from being formed by penetration of the foreign substance or debris through the second inorganic encapsulation film TIL2.

A maximum thickness O-TH1 of the organic encapsulation film OL at a portion overlapping the first spacers SPC1 may be greater than a maximum thickness O-TH2 of the organic encapsulation film OL at a portion overlapping the second spacers SPC2.

The organic encapsulation film OL may cover the second spacers SPC2. The maximum thickness O-TH2 of the organic encapsulation film OL at a portion overlapping the second spacers SPC2 may be smaller than the thickness TH2 of the second spacers SPC2.

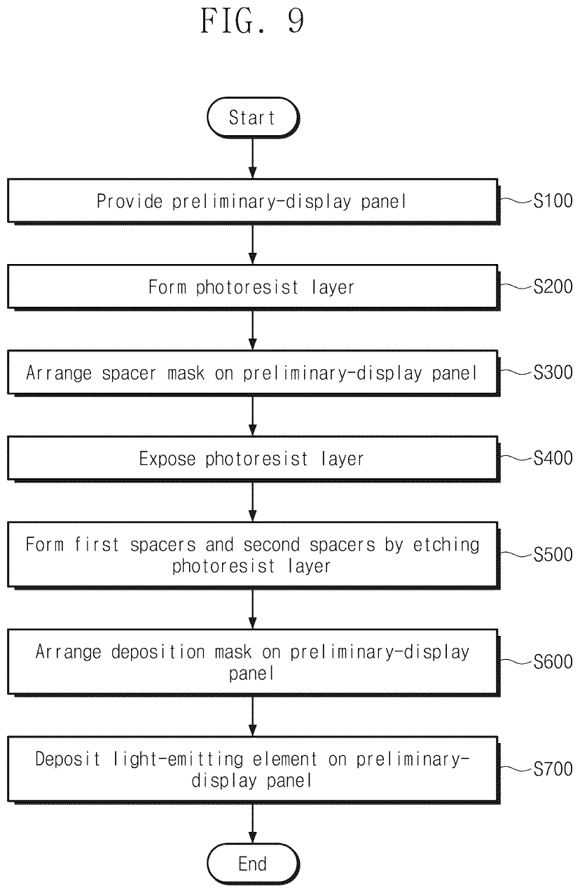

FIG. 9 is a flow chart of a manufacturing method for a display panel according to some example embodiments of the inventive concepts. It is understood that additional operations can be provided before, during, and after the operations in FIG. 9, and some of the operations described below can be replaced or eliminated, for additional embodiments of the method. The order of the operations/processes may be interchangeable, or two or more operations can be performed simultaneously.

The method may include providing a preliminary-display panel including a base layer and a pixel definition layer disposed on the base layer and having pixel openings defined therein (S100), forming a photoresist layer on the pixel definition layer (S200), arranging, on the preliminary-display panel, a spacer mask having first mask openings and second mask openings defined therein (S300), exposing the photoresist layer (S400), and forming first spacers and second spacers by etching the photoresist layer (S500).

The manufacturing method for a display panel may further include arranging, on the preliminary-display panel, a deposition mask having deposition openings defined therein (S600) and depositing a light-emitting element on the preliminary-display panel through the deposition mask (S700).

FIGS. 10A, 10B, 10C, 10D, and 10E are diagrams illustrating operations of a manufacturing method for a display panel according to some example embodiments of the inventive concepts.

As used herein, the term “preliminary-display panel P-DP” may refer to an incomplete display panel DP in a manufacturing process.

FIG. 10A illustrates a state in which the preliminary-display panel including the base layer BS and the pixel definition layer PDL is obtained, as in operation S100. The pixel definition layer PDL is disposed on the base layer and defines the pixel openings therein. For convenience of description, components disposed below a circuit element layer DP-CL are omitted in the illustration.

Thereafter, in FIG. 10B, the photoresist layer PR is formed on a pixel definition layer PDL, as in operation S200. A photoresist layer PR may cover the pixel definition layer PDL. The photoresist layer PR may cover first electrodes AE.

Thereafter, referring to FIG. 10C, the spacer mask may be arranged on the preliminary-display panel, as in operation S300, and the photoresist layer may be exposed, as in operation S400.

First mask openings OP1 and second mask openings OP2 may be defined in a spacer mask S-MK. The first mask openings OP1 may be openings for forming first spacers SPC1, and the second mask openings OP2 may be openings for forming second spacers SPC2.

An area of the first mask openings OP1 may be smaller than an area of the second mask openings OP2. Accordingly, the amount of light passing through the first mask openings OP1 may be more than the amount of light passing through the second mask openings OP2.

As described above, in a manufacturing method for a display panel, it may be possible to form the first spacers SPC1 and the second spacers SPC2 having different sizes by using the spacer mask S-MK having the first mask opening OP1 and the second mask opening OP2 having different areas.

However, example embodiments of the inventive concepts are not limited thereto. For example, in some example embodiments, the spacer mask S-MK may be a half-tone mask and exposure dose provided through a second opening may be less than exposure dose provided through a first opening.

Referring to FIG. 10D, the first spacers and the second spacers may be formed by etching the photoresist layer, as in operation S500. As an example, FIG. 10D illustrates that an exposed portion of the photoresist layer PR is cured and an unexposed portion of the photoresist layer PR is etched.

The second spacers SPC2 may be disposed adjacent to an outer or peripheral side of the preliminary-display panel P-DP relative to the first spacers SPC1.

Thereafter, referring to FIG. 10E, the deposition mask having the deposition openings defined therein may be arranged on the preliminary-display panel, as in operation S600 and the light-emitting element may be deposited on the preliminary-display panel through the deposition mask, as in operation S700. In some example embodiments, the light-emitting element may include the light-emitting elements OLED (FIG. 8). FIG. 10E may illustrate an enlarged portion of region BB′ of FIG. 10D.

For ease of illustration, a deposition mask MK disposed on the first spacers SPC1 and the second spacers SPC2 is shown in a dotted line.

In some example embodiments, the deposition mask MK may be a fine metal mask (FMM). Deposition openings MK-OP of the deposition mask MK may overlap pixel openings PDL-OP. However, example embodiments are not limited thereto. For example, the deposition mask MK may be an open mask.

The deposition mask MK may be disposed or positioned or arranged on the first spacers SPC1. The deposition mask MK may be in contact with an upper surface S1U of the first spacers SPC1.

The deposition mask MK may be partially bent. For example, as illustrated, in region CC′, the deposition mask MK may be bent and a portion of the deposition mask MK may be disposed on the second spacers SPC2. The portion of the deposition mask MK may be disposed on an upper surface S2U of the second spacers SPC2. However, example embodiments of the inventive concepts are not limited thereto. The deposition mask MK may not be bent, or even if the deposition mask MK is bent, a portion of the deposition mask MK may not be disposed on the second spacers SPC2.

Thereafter, the manufacturing method for a display panel may further include forming a first inorganic encapsulation film TIL1 on the pixel definition layer PDL, forming an organic encapsulation film OL on the first inorganic encapsulation film TIL1, and forming a second inorganic encapsulation film TIL2 on the organic encapsulation film OL.

The organic encapsulation film OL may be formed using one of a spin coating process, a slit coating process or an inkjet process.

The organic encapsulation film OL may cover the first spacers SPC1 and the second spacers SPC2.

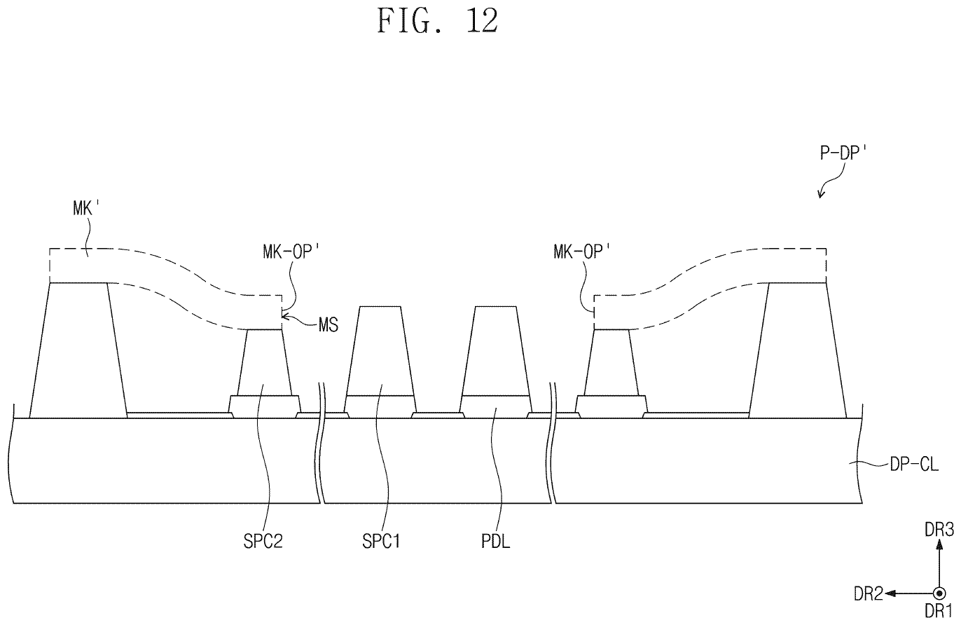

FIG. 11 is an enlarged plan view of a region of a display panel DP′ according to some example embodiments of the inventive concepts. FIG. 12 is a diagram illustrating a manufacturing process of a display panel according to some example embodiments of the inventive concepts.

Components that are the same as or similar in some respects to the components described with reference to FIGS. 1 to 10E are denoted as the same or similar reference numerals or symbols, and may be best understood with reference thereto.

A non-display region NDA may include a third region AA3. The third region AA3 may be adjacent to a second region AA2. First to third pixels PXA1, PXA2 and PXA3 and second spacers SPC2 may be disposed in the third region AA3. However, example embodiments of the inventive concepts are not limited thereto, and the first to third pixels PXA1, PXA2 and PXA3 disposed in the third region AA3 may be referred to as “dummy pixels”.

In a display panel DP′ according to some example embodiments, the second spacers SPC2 may be disposed in the non-display region NDA compared to the display panel DP described with reference to FIG. 7. Accordingly, the display panel DP′ may effectively prevent or avoid or limit “dent defect” that may occur in the non-display region NDA. For example, when a deposition mask MK′ (see FIG. 12) is an open mask, a side surface MS of the deposition mask MK′ defining a deposition opening MK-OP′ may be limited from causing a dent defect.

Referring to FIG. 12, a deposition mask MK′ having a deposition opening MK-OP′ defined therein may be arranged on a preliminary-display panel P-DP′, and light-emitting element may be deposited on the preliminary-display panel P-DP′ through the deposition mask MK′. In some example embodiments, the deposition mask MK′ may be an open mask.

In depositing the light-emitting element on the preliminary-display panel P-DP′, a side surface MS of the deposition mask MK′ defining the deposition opening MK-OP′ may overlap the second spacer SPC2. For example, the second spacers SPC2 disposed in the non-display region NDA may limit or restrain the side surface MS of the deposition mask MK′ from generating a dent defect at the preliminary-display panel P-DP′.

Accordingly, example embodiments disclosed herein, may provide a display panel having improved reliability in a deposition process and a method of manufacturing the same.

As described herein, any devices, systems, modules, portions, units, controllers, circuits, and/or portions thereof according to any of the example embodiments, and/or any portions thereof (including, without limitation, the display module DM, the processor PC, the memory MR, the power module PM, the smart glasses ED-2a, the head-mounted display ED-2b, the smart watch ED-2c, the automotive electronic devices ED-3, the smartphone ED-1a, the tablet PC ED-1b, the laptop ED-1c, the television ED-1d, and the desk monitor ED-1e, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure, as defined by the following claims. The present examples are to be considered as illustrative and not restrictive, and the intention is not to be limited to the details given herein. For example, the various elements or components may be combined or integrated in another system or certain features may be omitted, or not implemented.

What is claimed is:

1. A display panel comprising:
a base layer including a display region and a non-display region adjacent to the display region;
a pixel definition layer on the base layer and having pixel openings defined therein;
a display element layer including light-emitting elements in the pixel openings and first spacers on the pixel definition layer, the first spacers overlapping the display region, the first spacers not overlapping the pixel openings, and each first spacer having a first thickness;
a dam portion in the non-display region; and
second spacers between the dam portion and the first spacers, each second spacer having a second thickness smaller than the first thickness.

2. The display panel of claim 1, wherein the second spacers overlap the display region, and
in a cross-sectional view, a width of a bottom surface of each of the second spacers is smaller than a width of a bottom surface of each of the first spacers.

3. The display panel of claim 1, wherein the second thickness of each second spacer is 50% to 80% of the first thickness of each first spacer.

4. The display panel of claim 1, wherein a number of the second spacers per unit area is more than a number of the first spacers per unit area.

5. The display panel of claim 1, wherein an upper surface of the first spacers is flat, and
an upper surface of the second spacers is flat.

6. The display panel of claim 1, further comprising:
an encapsulation layer on the pixel definition layer, wherein the encapsulation layer comprises a first inorganic encapsulation film, an organic encapsulation film, and a second inorganic encapsulation film arranged in series on the pixel definition layer, and
a maximum thickness of the organic encapsulation film at a portion overlapping the first spacers is greater than a maximum thickness of the organic encapsulation film at a portion overlapping the second spacers.

7. The display panel of claim 6, wherein the organic encapsulation film covers the second spacers, and
the maximum thickness of the organic encapsulation film at the portion overlapping the second spacers is smaller than a thickness of the second spacers.

8. The display panel of claim 1, wherein the first spacers and the second spacers are formed through a same process and comprise a same material.

9. The display panel of claim 1, wherein each of the first thickness of the first spacers and the second thickness of the second spacers is smaller than a thickness of the dam portion.

10. The display panel of claim 1, wherein in a cross-sectional view, the first spacers and the second spacers each have a width decreasing in a direction away from the base layer.

11. The display panel of claim 1, wherein the first spacers and the second spacers each comprise a single layer.

12. A manufacturing method for a display panel, the manufacturing method comprising:
providing a preliminary-display panel including a base layer and a pixel definition layer disposed on the base layer and having pixel openings defined therein;
forming a photoresist layer on the pixel definition layer;
arranging, on the preliminary-display panel, a spacer mask having first mask openings and second mask openings defined therein;
exposing the photoresist layer; and
forming first spacers and second spacers by etching the photoresist layer,
wherein an area of the first mask openings is smaller than an area of the second mask openings.

13. The manufacturing method of claim 12, further comprising:
arranging, on the preliminary-display panel, a deposition mask having deposition openings defined therein; and
depositing a light-emitting element on the preliminary-display panel through the deposition mask,
wherein, in arranging the deposition mask, the deposition mask is arranged on the first spacers.

14. The manufacturing method of claim 13, wherein the deposition mask is a fine metal mask (FMM).

15. The manufacturing method of claim 13, wherein the deposition mask is an open mask,
the base layer comprises a display region and a non-display region adjacent to the display region, and
at least one second spacer is disposed in the non-display region.

16. The manufacturing method of claim 12, further comprising:
forming a first inorganic encapsulation film on the pixel definition layer;
forming an organic encapsulation film on the first inorganic encapsulation film; and
forming a second inorganic encapsulation film on the organic encapsulation film,
wherein the forming the organic encapsulation film is performed by one of a spin coating process, a slit coating process, and an inkjet process, and
a maximum thickness of the organic encapsulation film at a portion overlapping the first spacers is greater than a maximum thickness of the organic encapsulation film at a portion overlapping the second spacers.

17. The manufacturing method of claim 16, wherein the organic encapsulation film covers the second spacers, and
a thickness of the organic encapsulation film at the portion overlapping the second spacers is smaller than a thickness of the second spacers.

18. The manufacturing method of claim 12, wherein the base layer comprises a display region and a non-display region adjacent to the display region,
the first spacers and the second spacers overlap the display region, and
the second spacers are disposed closer to an outer side of the preliminary-display panel than the first spacers.

19. The manufacturing method of claim 12, wherein the spacer mask is a half-tone mask.

20. An electronic device comprising:
a display panel including,
a base layer including a display region and a non-display region adjacent to the display region, a pixel definition layer on the base layer and having pixel openings defined therein, a display element layer including light-emitting elements in the pixel openings and first spacers on the pixel definition layer, the first spacers overlapping the display region, the first spacers not overlapping the pixel openings, and each first spacer having a first thickness,
a dam portion in the non-display region, and
second spacers between the dam portion and the first spacers, each second spacer having a second thickness smaller than the first thickness;
a processor connected to the display panel; and
a window on the display panel.
